(19) United States
(12) Patent Application Publication
(10) Pub. No.: US 2015/0302925 A1
(43) Pub. Date: Oct. 22, 2015

(54) ELECTRONIC DEVICE INCLUDING SEMICONDUCTOR MEMORY AND OPERATION METHOD THEREOF

(71) Applicants: Byoung-Chan OH, Gyeonggi-do (KR); Ji-Hyae BAE, Gyeonggi-do (KR); Katsuyuki FUJITA, Tokyo (JP); Yutaka SHIRAI, Tokyo (JP)

(72) Inventors: Byoung-Chan OH, Gyeonggi-do (KR); Ji-Hyae BAE, Gyeonggi-do (KR); Katsuyuki FUJITA, Tokyo (JP); Yutaka SHIRAI, Tokyo (JP)

(21) Appl. No.: 14/560,819

(22) Filed: Dec. 4, 2014

(30) Foreign Application Priority Data
Apr. 17, 2014 (KR) 10-2014-0045909

(51) Int. Cl. G11C 13/00

(52) U.S. Cl. CPC G11C 13/0069; G11C 13/004

(57) ABSTRACT

Disclosed is an electronic device including a semiconductor memory. The semiconductor memory includes a bit line, a source line, a plurality of resistive memory cells among which a selected resistive memory cell forms a current path between the bit line and the source line, a sense amplifier suitable for sensing data of the bit line in an active operation, a latch suitable for latching data sensed by the sense amplifier in the active operation, a write control unit suitable for comparing data latched in the latch with write data in a write operation, and a write driver suitable for driving the bit line and the source line based on a comparison result of the write control unit and the write data in the write operation.

### CROSS-REFERENCE TO RELATED APPLICATIONS

The present application claims priority of Korean Patent Application No. 10-2014-0045909, filed on Apr. 17, 2014, which is incorporated herein by reference in its entirety.

### BACKGROUND

1. Field

Exemplary embodiments of the present invention relate to a memory circuit or device, and an application thereof in an electronic device.

2. Description of the Related Art

Recently as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

Various embodiments are directed to an electronic appliance in which an unnecessary write operation is prevented from being performed, so that current consumption is reduced and endurance is improved.

In one aspect, an electronic device is provided to include a semiconductor memory that includes: a bit line; a source line; a plurality of resistive memory cells among which a selected resistive memory cell forms a current path between the bit line and the source line; a sense amplifier suitable for sensing data of the bit line in an active operation; a latch suitable for latching the data sensed by the sense amplifier in the active operation; a write control unit suitable for comparing a value stored in the latch with write data in a write operation; and a write driver suitable for driving the bit line and the source line in response to a comparison result of the write control unit and the write data in the write operation.

Implementations of the above electronic device may include one or more the following.

The value stored in the latch may be updated to the write data after a comparison operation of the write control unit.

When the write control unit determines that the value stored in the latch is equal to the write data, the write driver may be deactivated, and when the write control unit determines that the value stored in the latch is not equal to the write data, the write driver may drive a current from the bit line to the source line or from the source line to the bit line according to a logic value of the write data.

The write control unit may be activated or deactivated according to a mode, and when the write control unit is deactivated, the write driver may drive the bit line and the source line in response to the write data regardless of the comparison result.

Each of the plurality of resistive memory cells may comprise: a variable resistance element having a resistance value that is changed according to a logic value of stored data; and a switch element suitable for forming a current path between the bit line and the source line through the variable resistance element.

The variable resistance element may include one or more of metal oxide, phase change material, and a structure in which a tunnel barrier layer is interposed between two ferromagnetic layers.

In accordance with the electronic device according to the aforementioned embodiments, an unnecessary write operation can be prevented from being performed, so that the current consumption of the electronic device can be reduced and endurance can be improved.

The electronic device may further include a microprocessor which includes: a control unit that is configured to receive a signal including a command from an outside of the microprocessor, and performs extracting, decoding of the command, or controlling input or output of a signal of microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory unit that includes the variable resistance element is part of the memory unit in the microprocessor.

The electronic device may further include a processor which includes: a core unit configured to perform, based on a command inputted from an outside of the processor, an operation corresponding to the command, by using data; a cache memory unit configured to store data for performing the operation data corresponding to a result of performing the operation, or an address of data for which the operation is performed; and a bus interface connected between the core unit and the cache memory unit, and configured to transmit data between the core unit and the cache memory unit, wherein the semiconductor memory unit that includes the variable resistance element is part of the cache memory unit in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between the processor, the auxiliary memory device or the main memory device and the outside, wherein the semiconductor memory unit that includes the variable resistance element is part of the auxiliary memory device or the main memory device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory unit that includes the variable resistance element is part of the storage device or the temporary storage device in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory unit that includes the variable resistance to element is part of the memory or the buffer memory in the memory system.

In another aspect, an operation method of a semiconductor memory included in an electronics device is provided. The method comprises: receiving an active command and a row address; generating read data from a memory cell of a row corresponding to the row address; storing the read data in a latch; receiving a write command and write data; and comparing data stored in the latch with the write data and determining whether to perform a write operation.

The method may further comprise: driving a bit line and a source line based on a logic value of the write data when it is determined to perform the write operation in the comparing and the determining,

The method may further comprise: after the determining, updating the write data in the latch.

In another aspect, an electronic device is provided that includes: a plurality of resistive memory cells selected by a row address in an active operation; a latch suitable for storing data of a resistive memory cell selected by the row address, among the resistive memory cells, in the active operation; a write control unit suitable for comparing data stored in the latch with write data in a write operation; and a write driver suitable for writing the write data in the resistive memory cell selected by the row address based on a comparison result of the write control unit in the write operation.

The write data may be updated in the latch after a comparison operation of the write control unit.

### BRIEF DESCRIPTION OF THE DRAWINGS

FIG. 1 illustrates an embodiment of a magnetic tunnel junction (MTJ) as one of structures in which a tunnel barrier layer is interposed between two ferromagnetic layers.

FIG. 2A and FIG. 2B are diagrams for explaining the principle of storing data for a variable resistance element 210.

FIG. 3 illustrates an example of the configuration of a memory circuit (device) including a variable resistance element.

FIG. 4 is a diagram illustrating the operation of a memory circuit of FIG. 3.

FIG. 5 shows an example of a configuration diagram of a microprocessor based on another embodiment of the disclosed technology.

FIG. 6 is a configuration diagram of a processor based on another embodiment of the disclosed technology.

FIG. 7 is a configuration diagram of a system based on another embodiment of the disclosed technology.

FIG. 8 is a configuration diagram of a data storage system based on another embodiment of the disclosed technology.

FIG. 9 is a configuration diagram of a memory system based on another embodiment of the disclosed technology.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate,

A semiconductor device according to embodiments of the present invention may include a variable resistance element. Hereinafter, the variable resistance element has a variable resistance characteristic, and may include a single layer or multiple layers. For example, the variable resistance element may include a material used in a RRAM, a PRAM, a MRAM, a FRAM and so on, for example, chalcogenide-based compound, transition metal compound, a ferroelectric, a ferromagnetic body, and so on. However, the present invention is not limited thereto, if the variable resistance element has a variable resistance characteristic in which it is switched between different resistant states based on a voltage or a current applied to both ends thereof.

In more detail, the variable resistance element may include metal oxide. The metal oxide, for example, may include transition metal oxide such as nickel oxide, a titanium oxide, a hafnium oxide, a zirconium oxide a tungsten oxide, or a cobalt oxide, a perovskite-based material such as STO (SrTiO) or PCMO (PrCaMnO), and so on. Such a variable resistance element may switch between different resistant states by the generation/destruction of a current filament due to the movement of a vacancy.

Furthermore, the variable resistance element may include a phase change material. The phase change material, for example, may include a chalcogenide-based material such as GST (Ge—Sb—Te). Such a variable resistance element may be stabilized in either a crystalline state or an amorphous state by heat, thereby switching between different resistant states.

Furthermore, the variable resistance element may include a structure in which a tunnel barrier layer is interposed between two ferromagnetic layers. The ferromagnetic layer may include a material such as NiFeCo or CoFe and the tunnel barrier layer may include a material such as Al₂O₃. Such a variable resistance element may switch between different resistant states based on the magnetization direction of the ferromagnetic layer. For example, when the magnetization directions of the two ferromagnetic layers are parallel to each other, the variable resistance element may be in a low resistance state, and when the magnetization directions of the two ferromagnetic layers are anti-parallel to each other, the variable resistance element may be in a high resistance state.

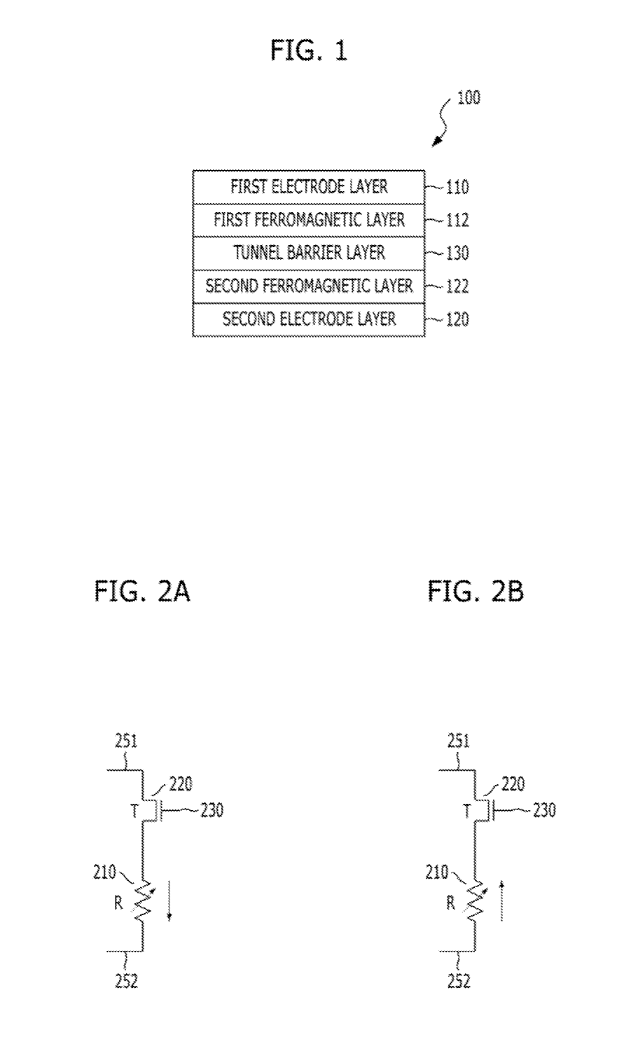

FIG. 1 illustrates an embodiment of a magnetic tunnel junction (MTJ) as a structure in which a tunnel barrier layer is interposed between two ferromagnetic layers.

As illustrated in FIG. 1, a magnetic tunnel junction 100 includes a first electrode layer 110 as a top electrode, a second electrode layer 120 as a bottom electrode, a first ferromagnetic layer 112, a second ferromagnetic layer 122, which are a pair of ferromagnetic layers, and a tunnel barrier layer 30 formed between the pair of ferromagnetic layers 112 and 122.

The first ferromagnetic layer 112 may be a free ferromagnetic layer having a magnetization direction that changes based on the direction of current applied to the magnetic tunnel junction 100, and the second ferromagnetic layer 122 is a finned ferromagnetic layer having a pinned magnetization direction.

The resistance value of such a magnetic tunnel junction 100 is changed based on the direction of the current, so that the magnetic tunnel junction 100 writes data “0” or “1” based on the resistance value thereof.

FIG. 2A and FIG. 2B are diagrams for explaining the principle of storing data in a variable resistance element 210. The variable resistance element 210 may be the magnetic tunnel junction 100 described in FIG. 1.

FIG. 2A is a diagram for explaining the principle of writing data having a ‘low’ logic value in the variable resistance element 210. In order to select the variable resistance element 210 in which data is to be stored, a word line 230 connected to the variable resistance element 210 is activated and a transistor 220 is turned on. When current flows from one end 251 to the other end 252, that is, from the first electrode layer 110 (the top electrode of the magnetic tunnel junction 100) to the second electrode layer 120 (the bottom electrode thereof) in FIG. 1 (the arrow direction), the magnetization direction of the first ferromagnetic layer 112 (a free ferromagnetic layer) and the magnetization direction of the second ferromagnetic layer 122 (a pinned ferromagnetic layer) are parallel with each other, and the variable resistance element 210 enters a low resistance state. When the variable resistance element 210 enters the low resistance state, it is defined that low' data is stored in the variable resistance element 210.

FIG. 2B is a diagram for explaining the principle of writing data having a ‘high’ logic value in the variable resistance element 210. Similarly, the word line 230 connected to the variable resistance element 210 is activated and the transistor 220 is turned on. When current flows from the other end 252 to the one end 251, that is, from the second electrode layer 120 to the first electrode layer 110 (the arrow direction), the magnetization direction of the first ferromagnetic layer 112 and the magnetization direction of the second ferromagnetic layer 122 are anti-parallel to each other, and the variable resistance element 210 enters a high resistance state. When the variable resistance element 210 enters the high resistance state, it is defined that ‘high’ data is stored in the variable resistance element 210.

Since a relatively large current flows in a write operation in which data is written in the variable resistance element 210, current consumption of a memory device including the variable resistance element 210 is greatly increased. When the number of times that data is written in the variable resistance element 210 increases, the variable resistance element may be degraded. Therefore, it is necessary to provide a technology capable of reducing the number of times of write operations, if possible.

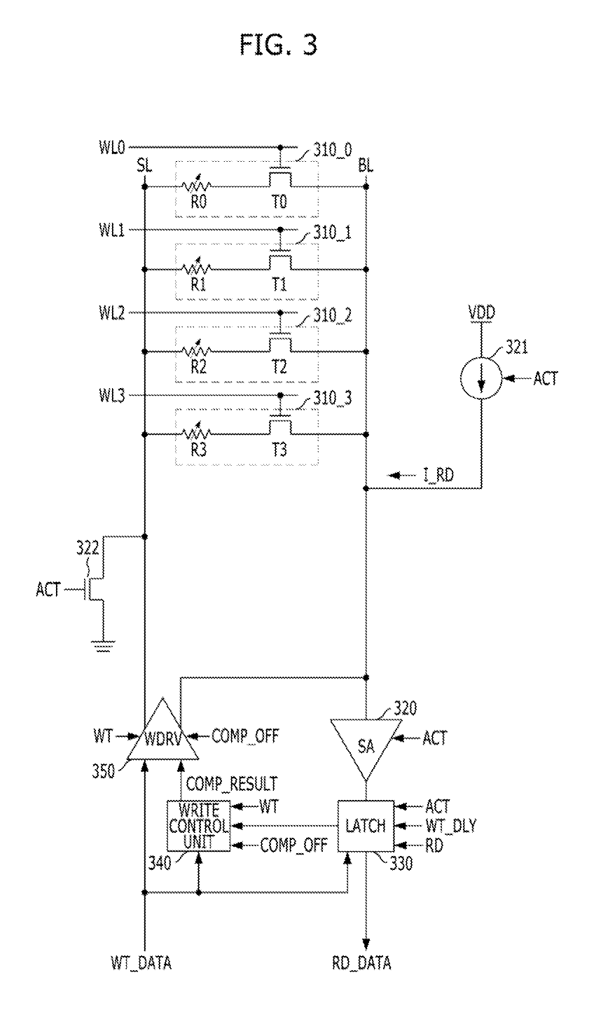

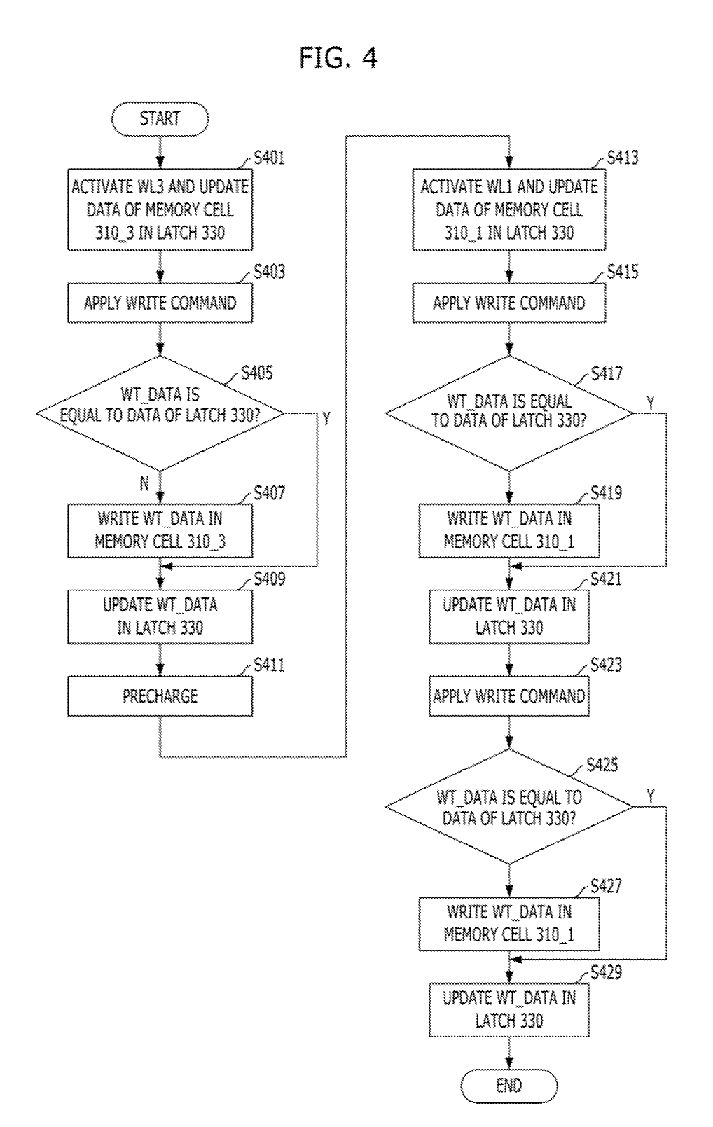

With reference to FIG. 3 and FIG. 4, embodiments of a memory circuit (device) having the aforementioned variable resistance element will be described,

In the following embodiments, an active operation, a read operation, and a write operation will be briefly described.

An active operation is performed when an active command is applied to the memory circuit, and a row address may be applied to the memory circuit together with the active command. In the active operation, a row (a word line) corresponding to the row address may be activated in the memory circuit. Furthermore, data of memory cells of the activated row may be sensed and amplified by a sense amplifier. The row (the word line) activated in the active operation may continuously maintain the activated state until the row (the word line) is deactivated by a precharge command.

A read operation is performed when a read command is applied to the memory circuit, and a column address may be applied to the memory circuit together with the read command, Data of a column (a pair of a bit line and a source line) corresponding to the column address applied in the read operation may be outputted from the memory circuit. Since the read operation may be performed after a row is previously selected and data of the selected row is sensed and amplified, the active operation should be performed before the read operation. For example, in a memory circuit including 100 rows×100 columns, when a third row is activated in the active operation, data of memory cells corresponding to the third row is sensed and amplified. In a subsequent read operation, when 32^{th} to 35^{th} columns are selected, data of the 32^{th} to 35^{th} columns, among the previously sensed and amplified data of the third row, is outputted from the memory circuit.

A write operation is performed when a write command applied to the memory circuit, and a column address may be applied to the memory circuit together with the write command. Furthermore, in the write operation, data to be written in the memory circuit may also be applied to the memory circuit. Since the write operation may be performed after a row is previously selected, the active operation should be performed before the write operation. In the write operation, data inputted to the memory circuit is written in memory cells of rows selected in the active operation and columns selected by the column address. For example, in a memory circuit including 100 rows×100 columns, when a 45^{th} row is activated in the active operation and fourth to seventh columns are selected in the write operation, data inputted to the memory circuit is written in memory cells of the 45^{th} row and the fourth to seventh columns.

FIG. 3 illustrates an example of the configuration of the memory circuit (device) including the variable resistance elements FIG. 3 illustrates a simple structure of a memory circuit including four rows and only one column in order to explain the principle of preventing unnecessary write operations.

Referring to FIG. 3, the memory circuit includes a bit line BL, a source line SL, word lines WL0 to WL3, resistive memory cells 310_0 to 310_3, a sense amplifier 320, a latch 330, a write control unit 340, a write driver 350, a current source 321, and a ground unit 322.

Among the signals of FIG. 3, an active signal ACT may be activated in the active operation. A read signal RD may be activated in the read operation. A write signal WT may be activated in the write operation. A delayed write signal WT_DLY is obtained by delaying the write signal WT, and a delay value of the delayed write signal WT_DLY may correspond to a time required for the write operation. Since the read operation and the rite operation are performed in a selected column the read signal RD and the write signal WT are activated when a corresponding column is selected. Since FIG. 3 illustrates only one column it is described that the read signal RD is activated in the read operation and the write signal WT is activated in the write operation after the one column is selected.

The resistive memory cells 310_0 to 310_3 may be connected between the bit line BL and the source line SL. The resistive memory cell 310_0 may include a variable resistance element R0 and a switch element T0, and the resistive memory cell 310_1 may include a variable resistance element RI and a switch element. Ti, and the resistive memory cell 310_2 may include a variable resistance element R2 and a switch element T2, and the resistive memory cell 310_3 may include a variable resistance element R3 and a switch element T3. Resistance values of the variable resistance elements R0 to R3 may be changed based on logic values of stored data. For example, when ‘row’ data is stored in the variable resistance element R1, the variable resistance element R1 may have a low resistance state, and when ‘high’ data is stored in the variable resistance element R1, the variable resistance element R1 may have a high resistance state. The switch elements T0 to T3 may form current paths between the bit line BL and the source line SL through the variable resistance elements R0 to R3 when the switch elements T0 to T3 are turned on. The switch elements T0 to T3 may be turned on/off under the control of the word lines WL0 to WL3. In the active operation, one word line selected by a row address among the word lines WL0 to WL3 may be activated, and a resistive memory cell corresponding to the activated word line among the resistive memory cells 310_0 to 310_3 may electrically connect the bit line BL and the source line SL to each other. For example, when the word line WL2 is activated in the active operation, the bit line BL and the source line SL may be electrically connected to each other by the resistive memory cell 310_2. Hereinafter, a resistive memory cell corresponding to an activated word line will be referred to as a selected resistive memory cell.

The current source 321 is activated when the active signal ACT is activated, and may supply a read current I_RD to the bit line BL being activated. The ground unit 322 is activated when the active signal ACT is activated, and may ground the source line SL being activated.

The sense amplifier 320 may sense and amplify data of a selected resistive memory cell by using the voltage of the bit line BL when the active signal ACT is activated. In the active operation, since a read current I_RD is supplied to the bit line BL through the current source 321 and the source line SL is grounded by the ground unit 322, the read current I_RD may flow from the bit line BL to the source line SL through the selected resistive memory cell. When the selected resistive memory cell has a high resistance state (that is, when ‘high’ data is stored), the voltage level of the bit line BL may be relatively high, and when the selected resistive memory cell has a low resistance state (that is, when low data is stored), the voltage level of the bit line may be relatively low. The sense amplifier 320 may sense data of the selected resistive memory cell based on whether the voltage level of the bit line BL is high or low.

The latch 330 may receive and store the data sensed by the sense amplifier 320 for an active period for which the active signal ACI is activated. Furthermore, when the delayed write signal WT_DLY is activated, the latch 330 may receive and store write data WT_DATA inputted to the memory circuit. Since a value stored in the latch 330 is updated in each active operation and each write operation, the value stored in the latch 330 may be data equal to the data stored in the selected resistive memory cell. The latch 330 may output the stored value as read data RD_DATA at the time of activation of the read signal RD.

The write control unit 340 operates in a period in which the write signal WT is activated, and may compare the value stored in the latch 330 with the write data WT_DATA inputted to the memory circuit when the write signal WT is activated. When the value stored in the latch 330 is equal to the write data WT_DATA, the write control unit 340 may output a comparison result COMP_RESULT as ‘low’, and when the value stored in the latch 330 is not equal to the write data WT_DATA, the write control unit 340 may output the comparison result COMP_RESULT as ‘high’.

The write driver 350 may drive the bit line BL and the source line SL in response to the comparison result COMP_RESULT of the write control unit 340 and the write data WT_DATA. When the comparison result COMP_RESULT is ‘low’, the write driver 350 may not drive the bit line BL and the source line SL. Since a “low” comparison result COMP_RESULT represents that current data stored in a selected resistive memory cell is equal to the write data WT_DATA, the write driver 350 does not need to write data in the selected resistive memory cell. However, when the comparison result COMP_RESULT is ‘high’, the write driver 350 may allow rite current to flow from the bit line BL to the source line SL or from the source line SL to the bit line BL based on the logic value of the write data WT_DATA. In this case, the write data WT_DATA may be written in the selected resistive memory cell.

Since the function of the write control unit 340 is deactivated when a comparison off signal COMP_OFF is activated, the write driver 350 may write the write data WT_DATA in the selected resistive memory cell regardless of the comparison result COMP_RESULT of the write control unit 340. The comparison off signal COMP_OFF may be activated in a mode of supporting an operation such as interrupt write. In the interrupt write, even when the write operation is not completed, a user may arbitrarily change data and write the data again. In the interrupt write, since it is not possible to guarantee that previous write data has been normally written in a resistive memory cell, the write data WT_DATA may be written in the resistive memory cell regardless of the comparison operation of the write control unit 340.

FIG. 4 is a diagram illustrating the operation of the memory circuit of FIG. 3. In FIG. 4, it is described as an example that the column illustrated in FIG. 3 is selected in the read and write operations. Furthermore, it is described as an example that the comparison off signal COMP_OFF is deactivated.

Referring to FIG. 4, the word line WL3 may be activated (S401). As the word line WL3 is activated, data stored in the resistive memory cell 310_3 may be sensed and amplified by the sense amplifier 320, and may be updated in the latch 330.

Next, the write data WT_DATA may be applied to the memory device together with the write command (S403). Then, it is possible to determine whether the write data WT_DATA is equal to the data stored in the latch 330 (S405). When the write data WT_DATA is equal to the data stored in the latch 330, it is not necessary to perform the write operation, and the write operation may be omitted. However, when the write data WT_DATA is not equal to the data stored in the latch 330, the write data WT_DATA may be written in the resistive memory cell 310_3 by the write driver 350 (S407).

When the time required for the write operation passes, regardless of whether the write operation has been performed or omitted, the delayed write signal WT_DLY may be activated and the write data WT_DATA may be updated in the latch (S409).

When a precharge command is activated, the activated word line WL3 may be deactivated (S411).

Then, the word line WL1 may be activated (S413). As the word line WL1 is activated, data stored in the resistive memory cell 310_1 may be sensed and amplified by the sense amplifier 320, and may be updated in the latch 330.

Next, the write data WT_DATA may be applied to the memory device together with the write command (S415). Then, it is possible to determine whether the write data WT_DATA is equal to the data stored in the latch 330 (S417). When the write data WT_DATA is equal to the data stored in the latch 330, it is not necessary to perform the write operation, and the write operation may be omitted. However, when the write data WT_DATA is not equal to the data stored in the latch 330, the write data WT_DATA may be written in the resistive memory cell 310_1 by the write driver 350 (S419).

When the time required for the write operation passes, regardless of whether the write operation has been performed or omitted, the delayed write signal WT_DLY may be activated and the write data WT_DATA may be updated in the latch (S421).

The write data WT_DATA may be applied again to the memory device together with the write command (S423). Then, it is possible to determine whether the write data WT_DATA is equal to the data stored in the latch 330 (S425). When the write data WT_DATA is equal to the data stored iii the latch 330, it is not necessary to perform the write operation, and the write operation may be omitted. However, when the write data WT_DATA is not equal to the data stored in the latch 330, the write data WT_DATA may be written in the resistive memory cell 310_1 by the write driver 350 (S427).

When the time required for the write operation passes, regardless of whether the write operation has been performed or omitted, the delayed write signal WT_DLY may be activated and the write data WT_DATA may be updated in the latch (S429).

Referring to FIG. 3 and FIG. 4, the write operation of the memory device may be omitted when data previously stored in the memory cell is equal to the write data. The unnecessary write operation is omitted so that it is possible to prevent unnecessary current consumption of the memory device and reduce the number of write operations so that it is possible to extend the lifespan of the memory device.

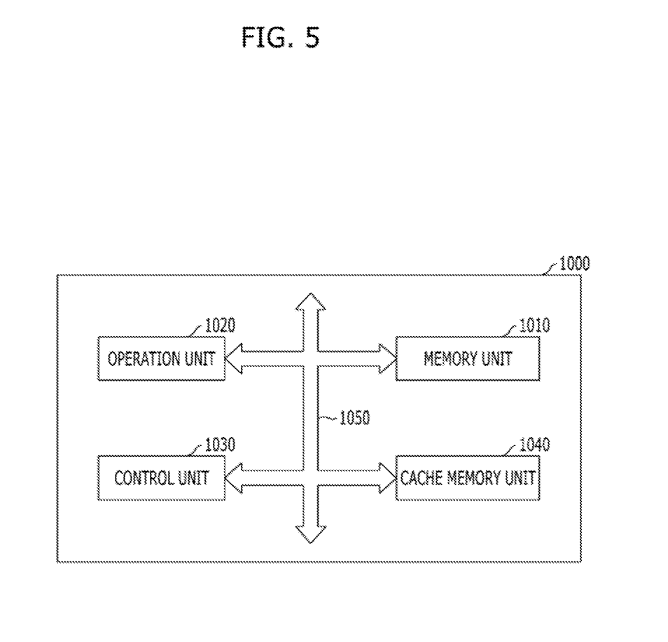

The above and other memory circuits or semiconductor devices based on the disclosed technology can be used in a range of devices or systems. FIGS. 5-9 provide some examples of devices or systems that can implement the memory circuits disclosed herein,

FIG. 5 shows an example of a configuration diagram of a microprocessor based on another implementation of the disclosed technology.

Referring to FIG. 5, a microprocessor 1000 may perform tasks for controlling and tuning a series of processes of receiving data from various external devices, processing the data, and outputting processing results to external devices. The microprocessor 1000 may include a memory unit 1010, an operation unit 1020 a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides the memory unit 1010 may include various registers. The memory unit 1010 may perform the function of temporarily storing data for which operations are to be performed by the operation unit 1020, result data of performing the operations and an address where data for performing of the operations are stored.

The memory unit 1010 may include one or more of the above-described memory circuits in accordance with the implementations. For example, the memory unit 1010 implementation may include a bit line, a source line, a plurality of resistive memory cells among which a selected memory cell forms a current path between the bit line and the source line, a sense amplifier suitable for sensing data of the bit line in an active operation, a latch suitable for latching the data sensed by the sense amplifier in the active operation, a write control unit suitable for comparing a value stored in the latch with write data in a write operation, and a write driver suitable for driving the bit line and the source line in response to a comparison result of the write control unit and the write data in the write operation. It is possible to prevent unnecessary current consumption of the memory device, and the number of times of the write operation is reduced. Through this, current consumption of the microprocessor 1000 can be reduced.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands and controlling input and output of signals of the microprocessor, and execute processing represented by programs.

The microprocessor 1000 according to the present implementation may additionally include a cache memory unit 1040 to which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

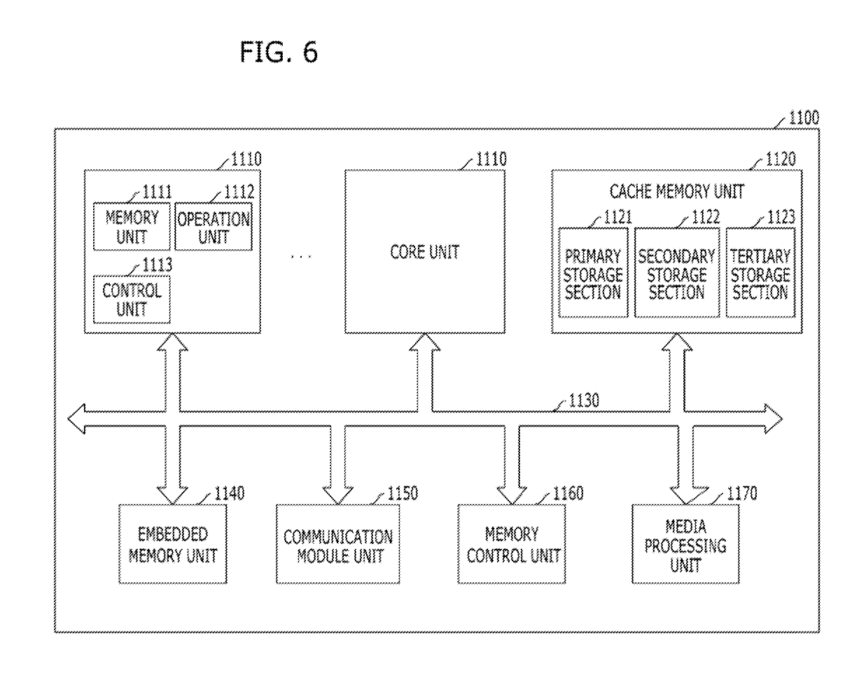

FIG. 6 is a configuration diagram of a processor based on another implementation of the disclosed technology.

Referring to FIG. 6, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and an address where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor, and execute processing represented by programs,

The cache memory unit 1120 is a part which temporarily stores data to compensate for a difference in data processing speed between the core unit 1110 operating at a high speed and an external device operating at a low speed. The cache memory unit 1120 may include a primary storage unit 1121, a secondary storage unit 1122 and a tertiary storage unit 1123. In general, the cache memory unit 1120 includes the primary and secondary storage units 1121 and 1122, and may include the tertiary storage unit 1123 in the case where high storage capacity is required. As the occasion demands, the cache memory unit 1120 may include an increased number of storage units. That is to say, the number of storage units which are included in the cache memory unit 1120 may be changed according to a design. The speeds at which the primary secondary and tertiary storage units 1121, 1122 and 1123 store and discriminate data may be the same or different, In the case where the speeds of the respective storage units 1121, 1122 and 1123 are different, the speed of the primary storage unit 1121 may be largest. At least one storage unit of the primary storage unit 1121, the secondary storage unit 1122 and the tertiary storage unit 1123 of the cache memory unit 1120 may include one or more of the above-described memory circuits in accordance with the implementations. For example, the cache memory unit 1120 implementation may include a bit line, a source line, a plurality of resistive memory cells among which a selected memory cell forms a current path between the bit line and the source line, a sense amplifier suitable for sensing data of the bit line in an active operation, a latch suitable for latching the data sensed by the sense amplifier in the active operation, a write control unit suitable for comparing a value stored in the latch with write data in a write operation, and a write driver suitable for driving the bit line and the source line in response to a comparison result of the write control unit and the write data in the write operation. It is possible to prevent unnecessary current consumption of the memory device, and the number of times of the write operation is reduced. Since the cache memory unit 1120 according to the present implementation may be improved in current consumption, the core unit 1110 may be improved in current consumption.

Although it was shown in FIG. 6 that all the primary, secondary and tertiary storage units 1121, 1122 and 1123 are configured inside the cache memory unit 1120, it is to be noted that all the primary, secondary and tertiary storage units 1121, 1122 and 1123 of the cache memory unit 1120 may be configured outside the core unit 1110 and may compensate for a difference in data processing speed between the core unit 1110 and the external device. Meanwhile, it is to be noted that the primary storage unit 1121 of the cache memory unit 1120 may be disposed inside the core unit 1110 and the secondary storage unit 1122 and the tertiary storage unit 1123 may be configured outside the core unit 1110 to strengthen the function of compensating for a difference in data processing speed. In another implementation, the primary and secondary storage units 1121, 1122 may be disposed inside the core units 1110 and tertiary storage units 1123 may be disposed outside core units 1110.The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage unit 1121 of the cache memory unit 1120 may be configured in each core unit 1110 in correspondence to the number of the plurality of core units 1110, and the secondary storage unit 1122 and the tertiary storage unit 1123 may be configured outside the plurality of core units 1110 in such a way as to be shared through the bus interface 1130. The processing speed of the primary storage unit 1121 may be larger than the processing speeds of the secondary and tertiary storage unit 1122 and 1123. In another implementation, the primary storage unit 1121 and the secondary storage unit 1122 may be configured in each core unit 1110 in correspondence to the number of the plurality of core units 1110, and the tertiary storage unit 1123 may be configured outside the plurality of core units 1110 in such a way as to be shared through the bus interface 1130.The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data prepared in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory) and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), and a memory with similar functions,

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (TDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband UWB), such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC to (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

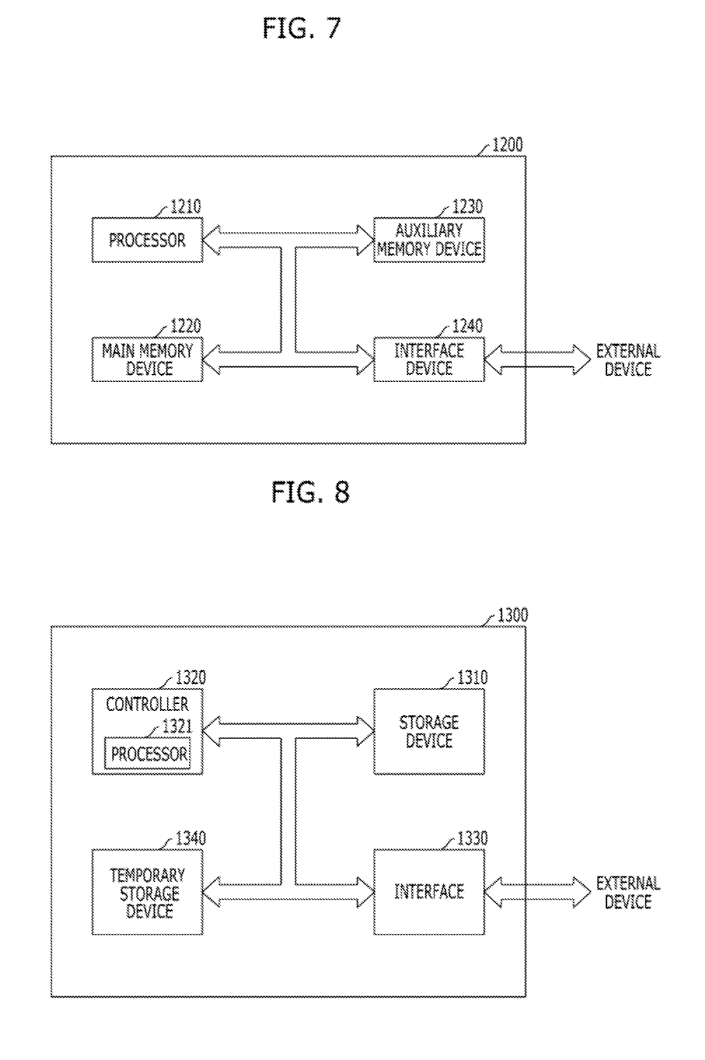

FIG. 7 is a configuration diagram of a system based on another implementation of the disclosed technology.

Referring to FIG. 7, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 decodes inputted commands and to processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP) and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 implementation may include a bit line, a source line, a plurality of resistive memory cells among which a selected memory cell forms a current path between the bit line and the source line, a sense amplifier suitable for sensing data of the bit line in an active operation, a latch suitable for latching the data sensed by the sense amplifier in the active operation, a write control unit suitable for comparing a value stored in the latch with write data in a write operation, and a write driver suitable for driving the bit line and the source line in response to a comparison result of the write control unit and the write data in the write operation. It is possible to prevent unnecessary current consumption of the memory device, and the number of times of the write operation is reduced. Through this, current consumption of the main memory device 1220 may be reduced. Since current consumption of the main memory device is reduced, current consumption of the system 1200 may be reduced.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 implementation may include a bit line, a source line, a plurality of resistive memory cells among which a selected memory cell forms a current path between the bit line and the source line, a sense amplifier suitable for sensing data of the bit line in an active operation, a latch suitable for latching the data sensed by the sense amplifier in the active operation, a write control unit suitable for comparing a value stored in the latch with write data in a write operation, and a write driver suitable for driving the bit line and the source line in response to a comparison result of the write control unit and the write data in the write operation. It is possible to prevent unnecessary current consumption of the memory device, and the number of times of the write operation is reduced. Since current consumption of the auxiliary memory device 1230 is reduced, current consumption of the system 1200 may be reduced.

Also, the auxiliary memory device 1230 may further include a data storage system (see the reference numeral 1300 of FIG. 14) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 8) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC) a compact flash (CF) card, and so on

The interface device 1240 may be to perform exchange of commands and data between the system 1200 of the present implementation and an external device. The interface device 1240 may be a keypad, a keyboard, a mouse, a speaker, a mike, a display, various human interface devices ( HIDs), a communication device and so on. The communication device may include a module capable of being connected with a wired network, a module capable of being connected with a wireless network and both of them.

The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 8 is a configuration diagram of a data storage system based on another implementation of the disclosed technology.

Referring to FIG. 8, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC) an embedded MMC (eMMC), a compact flash (CF) card, and so on, or be compatible with interfaces which are used in devices similar to the above mentioned devices.

In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other. The temporary storage device 1340 can store data temporarily implementation for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 implementation may include a bit line, a source line, a plurality of resistive memory cells among which a selected memory cell forms a current path between the bit line and the source line, a sense amplifier suitable for sensing data of the bit line in an active operation, a latch suitable for latching the data sensed by the sense amplifier in the active operation, a write control unit suitable for comparing a value stored in the latch with write data in a write operation, and a write driver suitable for driving the bit line and the source line in response to a comparison result of the write control unit and the write data in the write operation. It is possible to prevent unnecessary current consumption of the storage device 1310 or the temporary storage device 1340, and the number of times of the write operation is reduced. Since current consumption of the storage device 1310 or the temporary storage device 1340 may be reduced, current consumption of the data storage system 1300 may be reduced.

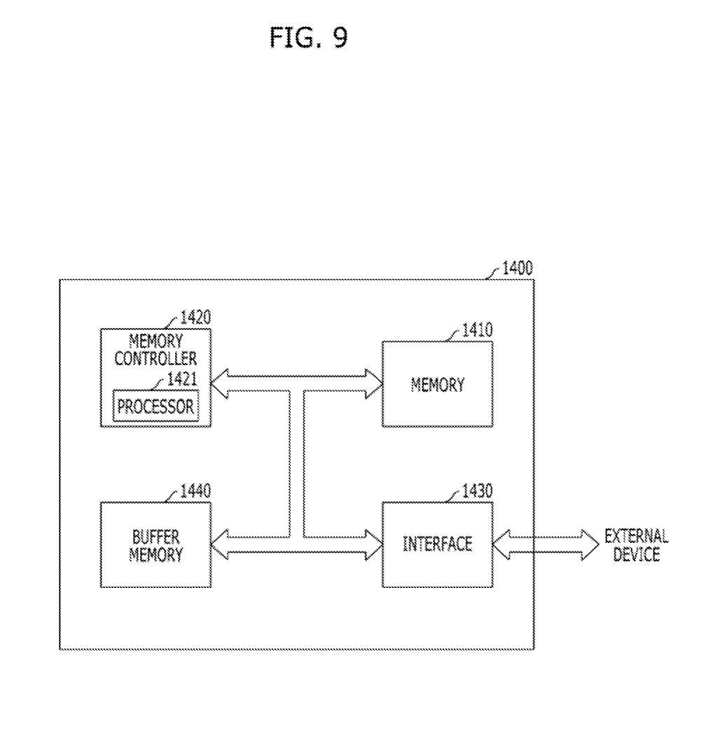

FIG. 9 is a configuration diagram of a memory system based on another implementation of the disclosed technology.

Referring to FIG. 9, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (rnSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 implementation may include a bit line, a source line, a plurality of resistive memory cells among which a selected memory cell forms a current path between the bit line and the source line, a sense amplifier suitable for sensing data of the bit line in an active operation, a latch suitable for latching the data sensed by the sense amplifier in the active operation, a write control unit suitable for comparing a value stored in the latch with write data in a write operation, and a write driver suitable for driving the bit line and the source line in response to a comparison result of the write control unit and the write to data in the write operation. It is possible to prevent unnecessary current consumption of the memory, and the number of times of the write operation is reduced. Since current consumption of the memory 1410 may be reduced, current consumption of the memory system may be reduced.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDRC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described memory circuits in accordance with the implementations. The buffer memory 1440 implementation may include a bit line, a source line, a plurality of resistive memory cells among which a selected memory cell forms a current path between the bit One and the source line, a sense amplifier suitable for sensing data of the bit One in an active operation, a latch suitable for latching the data sensed by the sense amplifier in the active operation, a write control unit suitable for comparing a value stored in the latch with write data in a write operation, and a write driver suitable for driving the bit line and the source line in response to a comparison result of the write control unit and the write data in the write operation. It is possible to prevent unnecessary current consumption of the buffer memory 1440, and the number of times of the write operation is reduced. Since current consumption of the buffer memory 1440 may be reduced, current consumption of the memory system 1400 may be reduced.

Moreover, the buffer memory 1440 according to the present implementation may further include an SRAM (static random access memory), a DRAM (dynamic random access memory), and so on, which have a volatile characteristic and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 5-9 based on the memory devices disclosed in this document may be implemented in various devices, systems or applications. Some examples include mobile phones or other portable communication devices, tablet computers, notebook or laptop computers, game machines, smart TV sets. TV set top boxes, multimedia servers, digital cameras with or without wireless communication functions, wrist watches or other wearable devices with wireless communication capabilities.

Although various embodiments have been described for illustrative purposes, it will be apparent to those skilled in the art that various changes and modifications may be made without departing from the spirit and scope of the invention as defined in the following claims.

What is claimed is:

1. An electronic device including a semiconductor memory, wherein the semiconductor memory comprises:
a bit line;
a source line;
a plurality of resistive memory cells among which a selected resistive memory cell forms a current path between the bit line and the source line;
a sense amplifier suitable for sensing data of the bit line in an active operation;
a latch suitable for latching data sensed by the sense amplifier in the active operation;
a write control unit suitable for comparing data latched in the latch with write data in a write operation; and
a write driver suitable for driving the bit line and the source line based on a comparison result of the write control unit and the write data in the write operation.

2. The electronic device according to claim 1, wherein the write data is updated in the latch after a comparison operation of the write control unit.

3. The electronic device according to claim 2, wherein, when the write control unit determines that the data latched in the latch is equal to the write data, the write driver is deactivated and when the write control unit determines that the data latched in the latch is not equal to the write data the write driver drives a current from the bit line to the source line or from the source line to the bit line based on a logic value of the write data.

4. The electronic device according to claim 1, wherein the write control unit is activated or deactivated based on a mode, and when the write control unit is deactivated, the write driver drives the bit line and the source line based on the write data regardless of the comparison result.

5. The electronic device according to claim wherein each of the plurality of resistive memory cells comprises:
a variable resistance element having a resistance value hat is changed based on a logic value of stored data; and
a switch element suitable for forming a current path between the bit line and the source line through the variable resistance element.

6. The electronic device according to claim 5, wherein the variable resistance element includes one or more of metal oxide, phase change material, and a structure in which a tunnel barrier layer is interposed between two ferromagnetic layers.

7. The electronic device according to claim further comprising a microprocessor which includes:
a control unit that is configured to receive a signal including a command from an outside of the microprocessor, and performs extracting, decoding of the command, or controlling input or output of a signal of microprocessor;
an operation unit configured to perform an operation based on a result from the control unit decoding the command; and
a memory unit configured to store data for performing the operation, data corresponding to a result of performing the operation, or an address of data for which the operation is performed,
wherein the semiconductor memory unit is part of the memory unit in the microprocessor.

8. The electronic device according to claim 1, further comprising a processor which includes:
a core unit configured to perform, based on a command inputted from an outside of the processor, an operation corresponding to the command, by using data
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory unit is part of the cache memory unit in the processor.

9. The electronic device according to claim 1, further comprising a processing system which includes:
a processor configured to decode a command received by the processor and control an operation for information based on a result of decoding the command;
an auxiliary memory device configured to store a program or decoding the command and the information;
a main memory device configured to call and store the program and the information from the auxiliary memory device such that the processor can perform the operation using the program and the information when executing the program; and
an interface device configured to perform communication between the processor, the auxiliary memory device or the main memory device and the outside,
wherein the semiconductor memory unit is part of the auxiliary memory device or the main memory device in the processing system.

10. The electronic device according to claim 1, further comprising a data storage system which includes:
a storage device configured to store data and conserve stored data regardless of power supply;
a controller configured to control input and output of data to and from the storage device according to a command inputted from an outside;
a temporary storage device configured to temporarily store data exchanged between the storage device and the outside; and
an interface configured to perform communication between at least one of the storage device, the controller and the temporary storage device and the outside,
wherein the semiconductor memory unit is part of the storage device or the temporary storage device in the data storage system.

11. The electronic device according to claim 1, further comprising a memory system which includes:
a memory configured to store data and conserve stored data regardless of power supply;
a memory controller configured to control input and output of data to and from the memory according to a command inputted from an outside;
a buffer memory configured to buffer data exchanged between the memory and the outside; and
an interface configured to perform communication between at least one of the memory, the memory controller and the buffer memory and the outside,
wherein the semiconductor memory unit is part of the memory or the buffer memory in the memory system.

12. An operation method of a semiconductor memory included in an electronic device, comprising:
receiving an active command and a row address;
generating read data from a memory cell of a row corresponding to the row address;
storing the read data in a latch;
receiving a write command and write data; and
comparing data stored in the latch with the write data and determining whether to perform a write operation.

13. The operation method according to claim 12, further comprising:
driving a bit line and a source line based on a logic value of the write data when it is determined to perform the write operation in the comparing and the determining.

14. The operation method according to claim 12, further, after the determining, comprising:
updating the v rite data in the latch.

15. An electronic device comprising:
a plurality of resistive memory cells selected by a row address in an active operation;
a latch suitable for storing data of a resistive memory cell selected by the row address, among the resistive memory cells, in the active operation;
a write control unit suitable for comparing data stored in the latch with write data in a write operation; and
a write driver suitable for writing the write data in the resistive memory cell selected by the row address based on a comparison result of the write control unit in the write operation.

16. The electronic device according to claim 15, wherein the write data is updated in the latch after a comparison operation of the write control unit.
